(19) United States
(12) Patent Application Publication
(10) Pub. No.: US 2024/0186222 A1
(43) Pub. Date: Jun. 6, 2024

(54) SEMICONDUCTOR DEVICE

(71) Applicant: Mitsubishi Electric Corporation, Tokyo (JP)

(72) Inventor: Narumi MATSUSHITA, Tokyo (JP)

(73) Assignee: Mitsubishi Electric Corporation, Tokyo (JP)

(21) Appl. No.: 18/460,518

(22) Filed: Sep. 1, 2023

(30) Foreign Application Priority Data
Dec. 2, 2022 (JP) 2022-193212

(51) Int. Cl. H01L 23/495; H01L 23/00

(52) U.S. Cl. CPC H01L 23/49562; H01L 24/45; H01L 24/48; H01L 2224/45139; H01L 2224/45144; H01L 2224/48247; H01L 2924/10253; H01L 2924/13055

(57) ABSTRACT

An object is to provide a technique capable of reducing in the size of a semiconductor device. A semiconductor device includes a second semiconductor switching element having a rectangular shape with a long side facing a first semiconductor switching element in plan view, having an area smaller than that of the first semiconductor switching element in plan view, and composed of a wide bandgap semiconductor, and a plurality of first wires connecting the first semiconductor switching element and the second semiconductor switching element, being 40 μm or less in diameter, and composed of silver or gold.

### BACKGROUND OF THE INVENTION

### Field of the Invention

The present disclosure relates to a semiconductor device.

### Description of the Background Art

In recent years, there has been proposed a technique of connecting an emitter terminal of an Insulated Gate Bipolar Transistor (IGBT) and a source terminal of a Metal Oxide Semiconductor Field Effect Transistor (MOSFET) with a wire (for example, Japanese Patent Application Laid-Open No. 2014-130909). From the viewpoint of current density, in typical practice, power chips such as IGBTs and MOSFETs are connected by a thick wire being 200 to 400 μm in diameter and made of aluminum.

However, for example, in the commonly used wedge bonding method for wire bonding for thick wires, a bonding area on the order of millimeters is typically required. Accordingly, the bonding area for the thick wire is relatively large, which has remained a problem of the size of the semiconductor device not being reduced.

### SUMMARY

The present disclosure has been made in view of the above problem and has an object to provide a technique capable of reducing the size of the semiconductor device.

According to the present disclosure, a semiconductor device includes a first semiconductor switching element composed of silicon, a second semiconductor switching element having a rectangular shape with a long side facing the first semiconductor switching element in plan view, having an area smaller than that of the first semiconductor switching element in plan view, and composed of a wide bandgap semiconductor, and a plurality of first wires connecting the first semiconductor switching element and the second semiconductor switching element, being 40 μm or less in diameter, and composed of silver or gold.

The reduction in size of the semiconductor device is enabled.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view illustrating a configuration of a semiconductor device according to Embodiment 1;

FIG. 2 is an enlarged plan view illustrating a part of the configuration of the semiconductor device according to Embodiment 1;

FIG. 3 is an enlarged plan view illustrating a part of the configuration of a semiconductor device according to Modification 1;

FIG. 4 is a side view illustrating a part of a configuration of a semiconductor device according to Modification 2;

FIG. 5 is an enlarged plan view illustrating a part of a configuration of a semiconductor device according to Modification 3;

FIG. 6 is an enlarged plan view illustrating a part of the configuration of the semiconductor device according to Modification 3;

FIG. 7 is an enlarged plan view illustrating a part of the configuration of the semiconductor device according to Modification 3;

FIG. 8 is an enlarged plan view illustrating a part of the configuration of the semiconductor device according to Modification 3; and

FIG. 9 is an enlarged plan view illustrating a part of a configuration of a semiconductor device according to Modification 4.

### DESCRIPTION OF THE PREFERRED EMBODIMENTS

Hereinafter, Embodiments will be described with reference to the attached drawings. Features described in each of following Embodiments are examples, and not all features are necessarily essential. In addition, in the description given below, the same or similar components are given the same or similar reference numerals in a plurality of Embodiments, and components that are different will be mainly described. Also, in the following description, terms indicating specific positions or directions such as “upper”, “lower”, “left”, “right”, “front”, and “back” may not necessarily coincide with the positions or directions at the time of implementation.

### Embodiment 1

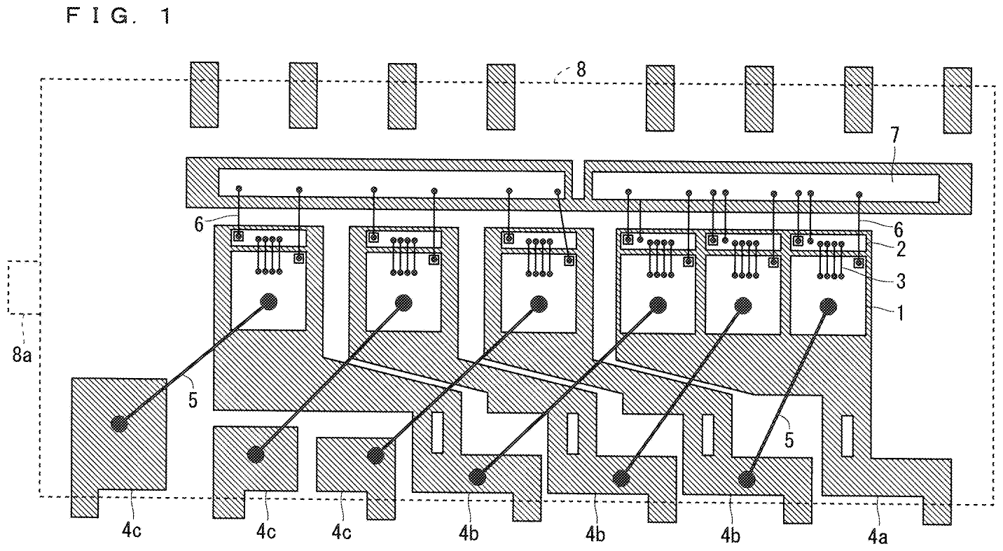

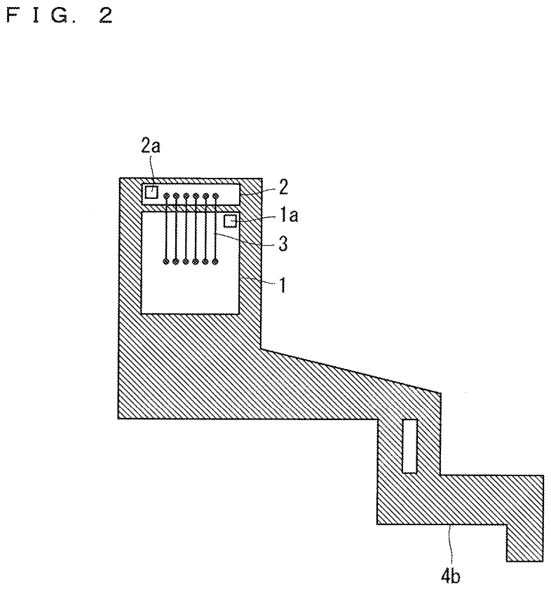

FIG. 1 is a plan view illustrating a configuration of a semiconductor device according to Embodiment 1 and FIG. 2 is an enlarged plan view illustrating a part of the configuration of FIG. 1. The semiconductor device of FIG. 1 includes a first semiconductor switching element 1, a second semiconductor switching element 2, a plurality of chip wires 3, lead frames 4a, 4b, 4c, a lead wire 5, a gate wire 6, a control chip 7, and a scaling resin 8.

The first semiconductor switching element 1 is composed of silicon. The second semiconductor switching element 2 has a smaller area than the first semiconductor switching element 1 in plan view, and is composed of a wide bandgap semiconductor. The wide bandgap semiconductor includes, for example, silicon carbide (SiC), gallium nitride (GaN), diamond, and the like. The second semiconductor switching element 2 composed of a wide bandgap semiconductor is capable of stable operation under higher temperature and higher voltage and faster switching speed than the first semiconductor switching element 1 composed of silicon.

Hereinafter, a configuration in which the first semiconductor switching element 1 is an Insulated Gate Bipolar Transistor (IGBT) and the second semiconductor switching element 2 is a Metal Oxide Semiconductor Field Effect Transistor (MOSFET) will be described as an example. However, the first semiconductor switching element 1 and the second semiconductor switching element 2 may also be, for example, Metal Oxide Semiconductor Field Effect Transistors (MOSFETs), IGBTs, and Reverse Conducting-IGBTs (RC-IGBTs).

In FIG. 2, a gate pad 1a and an emitter terminal are provided on the front side of the first semiconductor switching element 1, and a collector terminal is provided on the back side. In FIG. 2, a gate pad 2a and a source terminal are provided on the front side of the second semiconductor switching element 2, and a drain terminal is provided on the back side.

A plurality of chip wires 3, which area plurality of first wires, connect the emitter terminal of the first semiconductor switching element 1 and the source terminal of the second semiconductor switching element 2. Each of the plurality of chip wires 3 is 40 μm or less in diameter, and each of the plurality of chip wires 3 is composed of silver or gold.

Such chip wires 3 are relatively thin; therefore, a ball bonding method is adopted instead of a wedge bonding method for the bonding of the chip wires 3, for example. As a result, the bonding area of the chip wire 3 can be reduced to the order of micrometers, and design restrictions due to the bonding area can be relaxed.

In the following description, the chip wire 3 will be appropriately compared with a thick wire. The thick wire, which is thicker than the diameter of the chip wire 3, is for example, 200 μm or more and 400 μm or less in diameter, and is composed of aluminum, for example.

Increasing the number of chip wires 3 enables bringing the total current density of a plurality of chip wires 3 to be equivalent to the current density of the thick wire. Meanwhile, even if the number of chip wires 3 is increased, the total bonding area of a plurality of chip wires 3 is made smaller than the bonding area of thick wires because of the minuscule bonding area of each chip wire 3.

As described above, according to the configuration according to Embodiment 1, in which the first semiconductor switching element 1 and the second semiconductor switching element 2 are connected by the plurality of chip wires 3, reduction in size of the semiconductor device is enabled.

Further, in Embodiment 1, as illustrated in FIGS. 1 and 2, the second semiconductor switching element 2 has a rectangular shape with the long side facing the first semiconductor switching element 1 in plan view. The long side of the second semiconductor switching element 2 and the side of the first semiconductor switching element 1 facing the long side may be parallel or substantially parallel. According to such a configuration, a plurality of chip wires 3 can be arranged along the longitudinal direction of the second semiconductor switching element 2. Consequently, the length of the plurality of chip wires 3 can be shortened, so the reduction in size of the semiconductor device is enabled.

Further, in Embodiment 1, the longitudinal direction of the second semiconductor switching element 2 is perpendicular to the extending direction of the plurality of chip wires 3 in plan view. According to such a configuration, the length of the plurality of chip wires 3 can be shortened further, so the further reduction in size of the semiconductor device is enabled. However, the longitudinal direction of the second semiconductor switching element 2 may not be perpendicular to the extending direction of the plurality of chip wires 3, and may be substantially perpendicular, for example.

A first semiconductor switching element 1 and a second semiconductor switching element 2 are mounted on each of the lead frames 4a and 4b. In each of the lead frames 4a and 4b, a collector terminal of the mounted first semiconductor switching element 1 and a drain terminal of the mounted second semiconductor switching element 2 are electrically connected. The first semiconductor switching element 1 and the second semiconductor switching element 2 are not mounted on the lead frames 4c.

The lead wires 5 connect the first semiconductor switching element 1 mounted on the lead frame 4a and the lead frames 4b. Also, the lead wires 5 connect the first semiconductor switching elements 1 mounted on the lead frames 4b and the lead frames 4c. In Embodiment 1, the lead wires 5 are thick wires. The surface on the front side of the first semiconductor switching element 1 is relatively large and has a margin capable of accommodating the bonding area of the thick wire; therefore, there is no actual increase in the size of the semiconductor device even if the lead wires 5 are thick wires.

The gate wires 6 connect the gate pad 1a of the first semiconductor switching element 1 to the control chip 7, and the gate pad 2a of the second semiconductor switching element 2 to the control chip 7, respectively.

The control chip 7 controls the gate voltage of the first semiconductor switching element 1 and the gate voltage of the second semiconductor switching element 2 through the gate wires 6 to control the first semiconductor switching element 1 and the second semiconductor switching element 2. In Embodiment 1, the control chip 7 is provided on the side opposite to the first semiconductor switching element 1 with respect to the second semiconductor switching element 2 in a plan view, that is, the second semiconductor switching element 2 is provided between the control chip 7 and the first semiconductor switching element 1.

The control chip 7 on the right side in FIG. 1 is a High VoltAge IC (HVIC), and controls the gate voltages of three sets of first semiconductor switching element 1 and second semiconductor switching element 2 from the right side to control the current between the lead frame 4a and the lead frames 4b. The control chip 7 on the left side in FIG. 1 is a Low VoltAge IC (LVIC), and controls the gate voltages of three sets of first semiconductor switching element 1 and second semiconductor switching element 2 from the left side to control the current between the lead frames 4b and the lead frames 4c.

Although the number of control chips 7 is two in the example of FIG. 1, providing one control chip 7 may also be adoptable. Also, although in the example of FIG. 1, the number of sets of the first semiconductor switching element 1 and the second semiconductor switching element 2 is six, the number is not limited thereto.

The sealing resin 8 covers the first semiconductor switching elements 1, the second semiconductor switching elements 2, and the control chips 7. The sealing resin 8 is formed by injecting an uncured resin from the mold gate into the mold. Although FIG. 1 illustrates that the sealing resin 8 has a resin gate trace 8a that is a trace of the gate, the resin gate trace 8a is not essential in Embodiment 1.

### Summary of Embodiment 1

According to the above semiconductor device of Embodiment 1, the second semiconductor switching element 2 has a rectangular shape with the long side facing the first semiconductor switching element 1 in plan view. A plurality of chip wires 3 being 40 μm or less in diameter and composed of silver or gold connect the first semiconductor switching elements 1 and the second semiconductor switching elements 2, respectively. According to such a configuration, the reduction in size of the semiconductor device is enabled.

In Embodiment 1, the control chip 7 is provided on the side opposite to the first semiconductor switching element 1 with respect to the second semiconductor switching element 2 in a plan view. According to such a configuration, the connecting portions between the lead frames 4a, 4b, 4c and the lead wires 5 can be provided on the side opposite to the control chips 7 and the second semiconductor switching elements 2 with respect to the first semiconductor switching elements 1. As a result, the main current flows through the first semiconductor switching elements 1 and the lead wires 5; thereby reducing the current flowing through the second semiconductor switching elements 2. Consequently, a reduction in the number of chip wires 3 is enabled, and a reduction in manufacturing cost can be expected.

### <Modification 1>

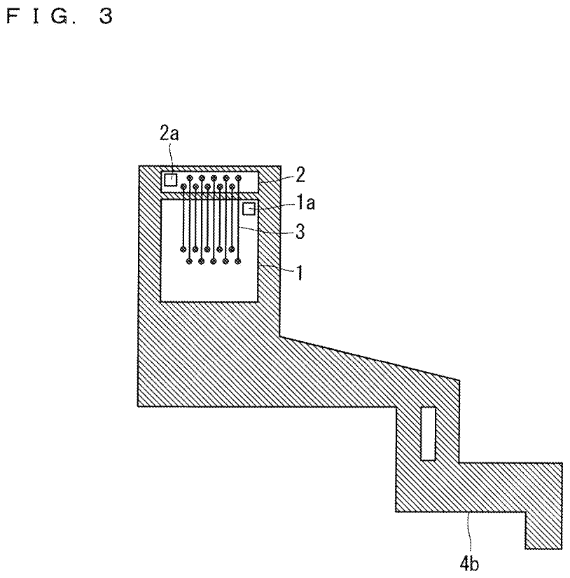

As illustrated in FIG. 3, the connection points of the plurality of chip wires 3 with the first semiconductor switching element 1 and the second semiconductor switching element 2 may be placed in an alternate manner along the arrangement direction of the plurality of chip wires 3 (that is, in a staggered pattern). According to such a configuration, the number of the plurality of chip wires 3 per unit area can be increased; therefore, increasing the total number of the plurality of chip wires 3 or reducing the total bonding area of the plurality of chip wires 3 is enabled. The same divided current flows through the plurality of chip wires 3; therefore, no substantial problem arises even if the chip wires 3 come into contact with each other.

### <Modification 2>

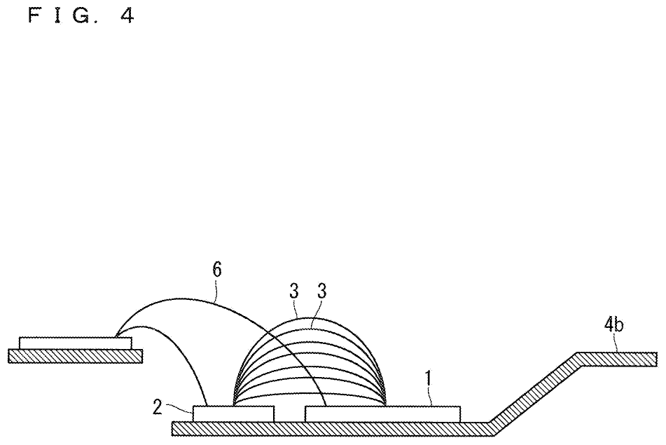

FIG. 4 is a side view illustrating a part of a configuration of a semiconductor device according to Modification 2, viewed from the resin gate trace 8a side in FIG. 1. As illustrated in FIG. 4, the loop heights of the plurality of chip wires 3 may increase in order of increasing distance from the resin gate trace 8a.

According to such a configuration, when the sealing resin 8 is formed, the flow of the resin injected from the mold gate can be suppressed while passing through the plurality of chip wires 3. For this reason, providing a component with weak mechanical strength on the opposite side of the mold gate with respect to the plurality of chip wires 3 enables the suppression of defects in the component due to the flow of resin. In the example in FIG. 4, the component is represented by a relatively long gate wire 6 connecting the first semiconductor switching element 1 and the control chip 7, and according to the above configuration, disconnection of the gate wire 6 can be suppressed.

### <Modification 3>

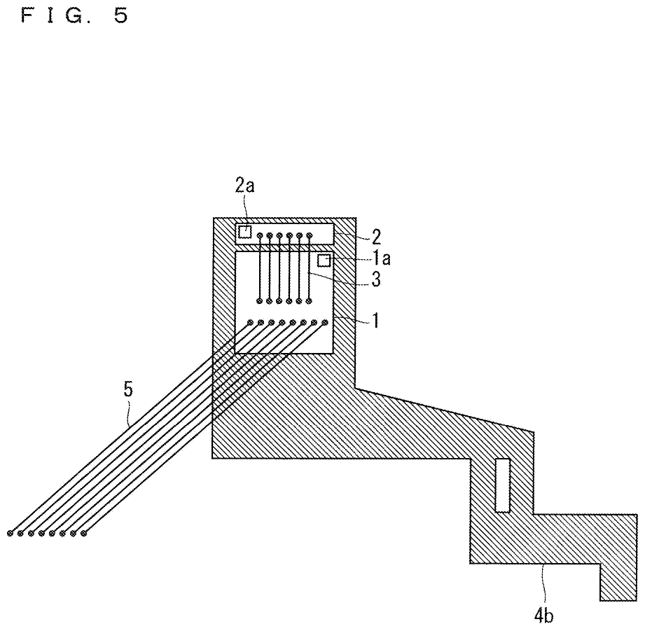

In the configuration of FIG. 1 of Embodiment 1, the lead wires 5 are thick wires, however they are not limited thereto. As illustrated in FIG. 5, the lead wires 5, which are second wires, are 40 μm or less in diameter and may be wires composed of silver or gold as with the plurality of chip wires 3.

In short, the lead wires 5 connecting the first semiconductor switching element 1 mounted on the lead frame 4a which is a first lead frame and the lead frame 4b which are the second lead frame may be wires of 40 μm or less in diameter. Also, the lead wires 5 connecting the first semiconductor switching element 1 mounted on the lead frame 4b which is the first lead frame and the lead frame 4c which are the second lead frame may also be wires of 40 μm or less in diameter.

According to such a configuration, the bonding area of the lead wires 5 can be made small, thereby, ensuring the reduction in the size of the semiconductor device. Also, adopting the same wires for the chip wires 3 and the lead wires 5 improves manufacturability.

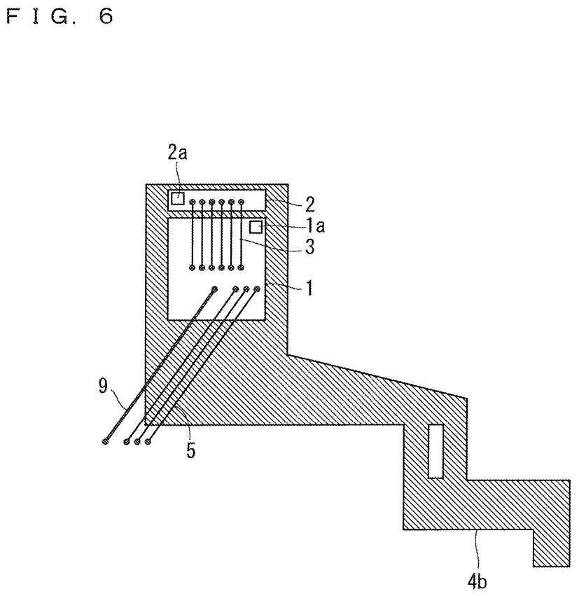

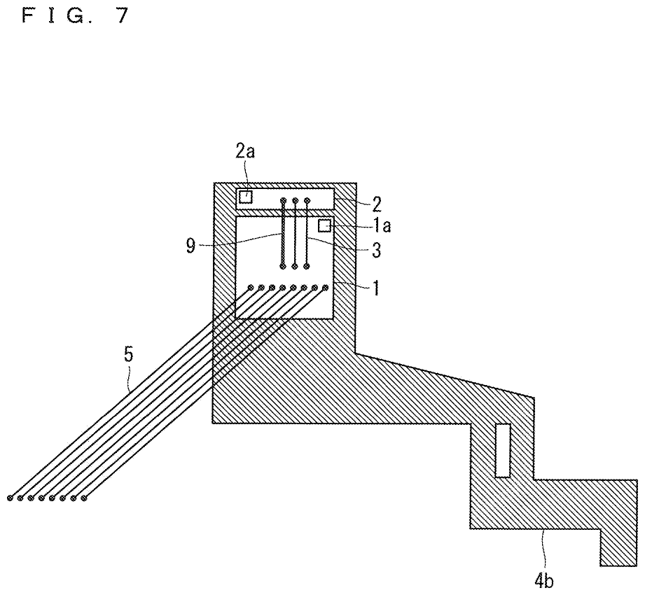

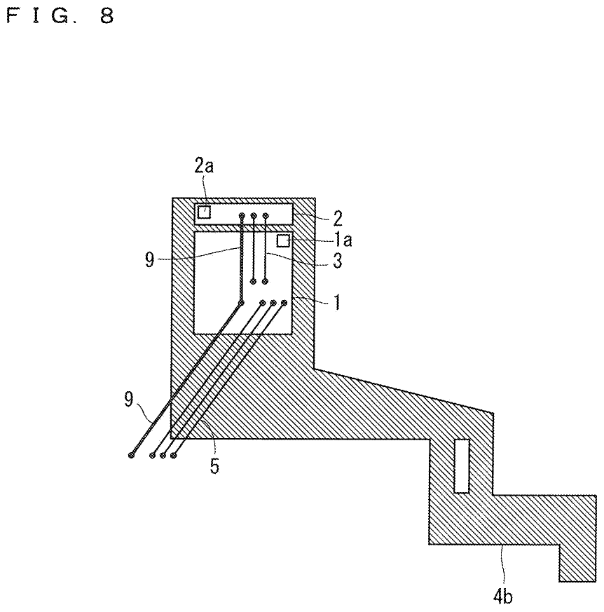

Further, as illustrated in FIGS. 6 to 8, a thick wire 9, which is a third wire having a diameter larger than that of the chip wires 3, may further be included. As illustrated in FIG. 6, the thick wire 9 may connect the first semiconductor switching elements 1 mounted on the lead frames 4a, 4b and the lead frames 4b, 4c, respectively, in coordination with lead wires 5 in FIG. 5. As illustrated in FIG. 7, the thick wire 9 may connect the first semiconductor switching element 1 and the second semiconductor switching element 2, in coordination with chip wires 3 in FIG. 5. As illustrated in FIG. 8, the thick wires 9 may connect the first semiconductor switching elements 1 mounted on the lead frames 4a, 4b and the lead frames 4b, 4c, respectively, and may also connect the first semiconductor switching element 1 and the second semiconductor switching element 2.

According to such a configuration, the thick wires 9 that are difficult to disconnect are adopted, thereby improving the reliability of the semiconductor device. Also, the current density of each path can be sufficiently secured.

### <Modification 4>

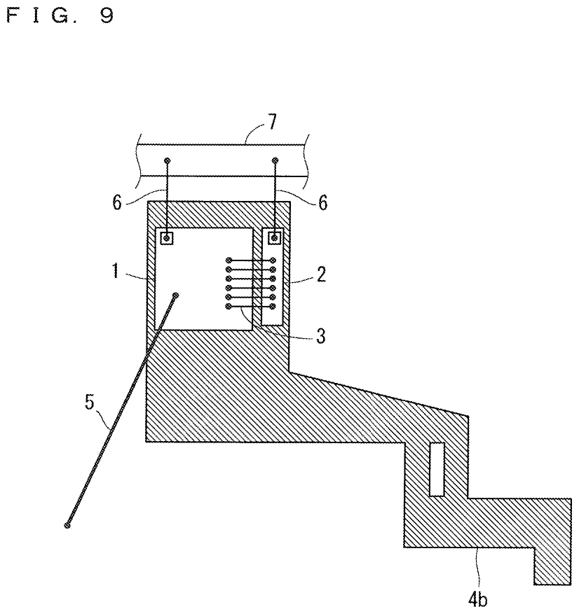

As illustrated in FIG. 9, fourth wires are the gate wires 6, one of which connects the first semiconductor switching element 1 and the control chip 7, and another of which connects the second semiconductor switching element 2 and the control chip 7. The gate wires 6 may extend in a direction perpendicular to the direction in which the first semiconductor switching element 1 and the second semiconductor switching element 2 are arranged. With such a configuration, the length of the gate wire 6 can be shortened, so disconnection of the gate wire 6 during injection of the sealing resin 8 can be suppressed.

It should be noted that Embodiment can be appropriately modified or omitted.

Hereinafter, the aspects of the present disclosure will be collectively described as Appendices.

### Appendix 1

A semiconductor device comprising:
a first semiconductor switching element composed of silicon;
a second semiconductor switching element having a rectangular shape with a long side facing the first semiconductor switching element in plan view, having an area smaller than that of the first semiconductor switching element in plan view, and composed of a wide bandgap semiconductor; and
a plurality of first wires connecting the first semiconductor switching element and the second semiconductor switching element, being 40 μm or less in diameter, and composed of silver or gold.

### Appendix 2

The semiconductor device according to Appendix 1, wherein in plan view, a longitudinal direction of the second semiconductor switching element is perpendicular to an extending direction of the plurality of first wires.

### Appendix 3

The semiconductor device according to Appendix 1 or 2, wherein connection points of the plurality of first wires with the first semiconductor switching element and the second semiconductor switching element are placed along an arrangement direction of the plurality of first wires in an alternate manner.

### Appendix 4

The semiconductor device according to any one of Appendices 1 to 3, further comprising:
a control chip configured to control the first semiconductor switching element and the second semiconductor switching element; and
a sealing resin having a resin gate trace and covering the first semiconductor switching element, the second semiconductor switching element, and the control chip, wherein
loop heights of the plurality of first wires increase in order of increasing distance from the resin gate trace.

### Appendix 5

The semiconductor device according to any one of Appendices 1 to 3, further comprising
a control chip configured to control the first semiconductor switching element and the second semiconductor switching element, wherein
in a plan view, the control chip is provided on a side opposite to the first semiconductor switching element with respect to the second semiconductor switching element.

### Appendix 6

The semiconductor device according to any one of Appendices 1 to 5, further comprising:
a first lead frame on which the first semiconductor switching element and the second semiconductor switching element are mounted;
a second lead frame; and
a plurality of second wires being 40 μm or less in diameter and connecting the first semiconductor switching element mounted on the first lead frame and the second lead frame.

### Appendix 7

The semiconductor device according to any one of Appendices 1 to 5, further comprising:
a first lead frame on which the first semiconductor switching element and the second semiconductor switching element are mounted;
a second lead frame; and
a third wire connecting at least one of between the first semiconductor switching element mounted on the first lead frame and the second lead frame or between the first semiconductor switching element and the second semiconductor switching element and having a diameter larger than that of the first wires.

### Appendix 8

The semiconductor device according to any one of Appendices 1 to 3, further comprising:
a control chip configured to control the first semiconductor switching element and the second semiconductor switching element; and
fourth wires, one of which connects the first semiconductor switching element and the control chip, and an other of which connects the second semiconductor switching element and the control chip, and extending in a direction perpendicular to a direction in which the first semiconductor switching element and the second semiconductor switching element are arranged.

While the invention has been illustrated and described in detail, the foregoing description is in all aspects illustrative and not restrictive. It is therefore understood that numerous modifications and variations can be devised without departing from the scope of the invention.

What is claimed is:

1. A semiconductor device comprising:
a first semiconductor switching element composed of silicon;
a second semiconductor switching element having a rectangular shape with a long side facing the first semiconductor switching element in plan view, having an area smaller than that of the first semiconductor switching element in plan view, and composed of a wide bandgap semiconductor; and
a plurality of first wires connecting the first semiconductor switching element and the second semiconductor switching element, being 40 μm or less in diameter, and composed of silver or gold.

2. The semiconductor device according to claim 1, wherein
in plan view, a longitudinal direction of the second semiconductor switching element is perpendicular to an extending direction of the plurality of first wires.

3. The semiconductor device according to claim 1, wherein
connection points of the plurality of first wires with the first semiconductor switching element and the second semiconductor switching element are placed along an arrangement direction of the plurality of first wires in an alternate manner.

4. The semiconductor device according to claim 1, further comprising:
a control chip configured to control the first semiconductor switching element and the second semiconductor switching element; and
a sealing resin having a resin gate trace and covering the first semiconductor switching element, the second semiconductor switching element, and the control chip, wherein
loop heights of the plurality of first wires increase in order of increasing distance from the resin gate trace.

5. The semiconductor device according to claim 1, further comprising
a control chip configured to control the first semiconductor switching element and the second semiconductor switching element, wherein
in a plan view, the control chip is provided on a side opposite to the first semiconductor switching element with respect to the second semiconductor switching element.

6. The semiconductor device according to claim 1, further comprising:
a first lead frame on which the first semiconductor switching element and the second semiconductor switching element are mounted;
a second lead frame; and
a plurality of second wires being 40 μm or less in diameter and connecting the first semiconductor switching element mounted on the first lead frame and the second lead frame.

7. The semiconductor device according to claim 1, further comprising:
a first lead frame on which the first semiconductor switching element and the second semiconductor switching element are mounted;
a second lead frame; and
a third wire connecting at least one of between the first semiconductor switching element mounted on the first lead frame and the second lead frame or between the first semiconductor switching element and the second semiconductor switching element and having a diameter larger than that of the first wires.

8. The semiconductor device according to claim 1, further comprising:
a control chip configured to control the first semiconductor switching element and the second semiconductor switching element; and
fourth wires, one of which connects the first semiconductor switching element and the control chip, and an other of which connects the second semiconductor switching element and the control chip, and extending in a direction perpendicular to a direction in which the first semiconductor switching element and the second semiconductor switching element are arranged.
